(19) United States
(12) Patent Application Publication
(10) Pub. No.: US 2023/0087390 A1
(43) Pub. Date: Mar. 23, 2023

(54) METHOD FOR MONITORING ABNORMAL SENSORS DURING FABRICATION OF SEMICONDUCTOR STRUCTURE, ELECTRONIC DEVICE AND STORAGE MEDIUM

(71) Applicant: CHANGXIN MEMORY TECHNOLOGIES, INC., Hefei City (CN)

(72) Inventor: Xiaojun Liu, Hefei (CN)

(21) Appl. No.: 17/750,448

(22) Filed: May 23, 2022

(30) Foreign Application Priority Data
Sep. 17, 2021 (CN) 202111095217.1

(51) Int. Cl. H01L 21/66; H01L 21/67

(52) U.S. Cl. CPC H01L 22/10; H01L 21/67253; H01L 21/67294

(57) ABSTRACT

The disclosure provides a method for monitoring abnormal sensors during fabrication of a semiconductor structure, an electronic device and storage medium. The method includes: measurement data of a wafer passing through different measurement sites are acquired; a plurality of measurement data included in each measurement site are input to a first classifier to select a first plurality of measurement sites; a plurality of measurement data corresponding to the first plurality of selected measurement sites are input to second and third classifiers to select a second plurality of measurement sites; the measurement data corresponding to the plurality of measurement sites are input to the first, second and third classifiers respectively, to select a plurality of target sensors; and the score of each target sensor group is obtained, and a plurality of target sensors in the target sensor group with the highest score are defined as abnormal sensors.

### CROSS-REFERENCE TO RELATED APPLICATIONS

The present application claims priority to Chinese Pat. Application No. 202111095217.1, filed on Sep. 17, 2021. The disclosure of Chinese Pat. Application No. 202111095217.1 is hereby incorporated by reference in its entirety.

### BACKGROUND

In the manufacturing process of semiconductor products, there are many factors that affect the yield of the semiconductor products. If these factors can be eliminated as early as possible, the productivity and yield of the semiconductor products will be improved.

When the factors affecting the yield of the semiconductor products are judged, measurement data of sensors involved in sites where abnormal semiconductor products pass through are acquired first, and then these measurement data are analyzed one by one, so as to determine the factors (abnormal sensors) affecting the yield of the semiconductor products.

When there are too many measurement data to be analyzed, an existing abnormality analysis method needs to perform amount of analysis work, which will lead to the problem that the analysis efficiency is too slow when the factors affecting the yield of the semiconductor products are analyzed.

### SUMMARY

The disclosure relates to semiconductor manufacturing technologies, in particular to a method for monitoring abnormal sensors during fabrication of a semiconductor structure, an electronic device and storage medium.

According to one aspect, a method for monitoring abnormal sensors during fabrication of a semiconductor structure is provided in the disclosure, which includes the following operations. Measurement data of a wafer passing through different measurement sites are acquired. Herein, each measurement site includes a plurality of measurement sensors, and the measurement sensors are configured to acquire the measurement data of the wafer. A plurality of measurement data included in each measurement site are input to a first classifier to select a first plurality of measurement sites. A plurality of measurement data corresponding to the first plurality of selected measurement sites are input to a second classifier and a third classifier to obtain scores of a same measurement site in the second classifier and the third classifier, so as to select a second plurality of measurement sites. The measurement data corresponding to the second plurality of measurement sites are input to the first classifier, the second classifier and the third classifier respectively, to obtain scores of a plurality of measurement sensors included in a same measurement site, so as to select a plurality of target sensors. The plurality of target sensors are combined to form a plurality of target sensor groups. A score of each target sensor group is obtained according to the first classifier, the second classifier and the third classifier, so as to obtain scores corresponding to all target sensor groups. A plurality of target sensors included in a target sensor group with a highest score are defined as abnormal sensors.

According to another aspect, an electronic device is provided in the disclosure, which includes a processor and a memory in communication connection with the processor. The memory stores a computer execution instruction. The processor executes the computer execution instruction stored in the memory to implement the method for monitoring the abnormal sensors during fabrication of a semiconductor structure as described in the first aspect.

According to another aspect, a computer-readable storage medium is provided in the disclosure. The computer-readable storage medium stores a computer execution instruction, which, when executed, enables a computer to execute the method for monitoring the abnormal sensors during fabrication of a semiconductor structure as described in the first aspect.

### BRIEF DESCRIPTION OF THE DRAWINGS

The drawings herein are incorporated into and constitute a part of the specification, which illustrate embodiments in accordance with the disclosure and together with the specification are used to explain the principle of the disclosure.

FIG. 1 is an application scenario diagram of a method for monitoring abnormal sensors during fabrication of a semiconductor structure according to the disclosure.

FIG. 2 is a flowchart of a method for monitoring abnormal sensors during fabrication of a semiconductor structure according to an embodiment of the application.

FIG. 3 is a schematic diagram of a method for monitoring abnormal sensors during fabrication of a semiconductor structure according to an embodiment of the application.

FIG. 4 is a schematic diagram of an apparatus for monitoring abnormal sensors during fabrication of a semiconductor structure according to an embodiment of the disclosure.

FIG. 5 is a schematic diagram of an electronic device according to an embodiment of the disclosure.

Specific embodiments of the disclosure have been shown by the above-mentioned drawings, and more detailed descriptions will be made later. These drawings and written descriptions are not intended to limit the scope of the concept of the disclosure in any way, but to explain the concept of the disclosure to those skilled in the art with reference to specific embodiments.

### DETAILED DESCRIPTION

Exemplary embodiments will now be illustrated in detail, and examples thereof are shown in the accompanying drawings. When the following description refers to the accompanying drawings, unless otherwise indicated, like numerals in different drawings indicate the same or similar elements. The implementations described in the following exemplary embodiments do not represent all implementations consistent with the present disclosure. Rather, they are merely examples of devices and methods consistent with some aspects of the present disclosure as described in detail in the appended claims.

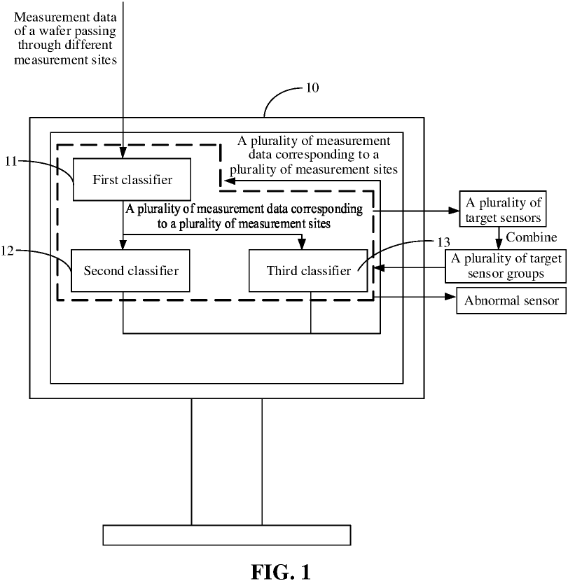

The method for monitoring abnormal sensors during fabrication of a semiconductor structure provided in the disclosure is applied to a computer device 10, such as a computer and a dedicated server in a laboratory. FIG. 1 is an application diagram of a method for monitoring abnormal sensors during fabrication of a semiconductor structure according to the disclosure. In FIG. 1, the computer device 10 is provided with a first classifier 11, a second classifier 12 and a third classifier 13. The computer device 10 inputs acquired measurement data of a wafer passing through different measurement sites to the first classifier 11, and preliminarily select a first plurality of measurement sites. Then, a plurality of measurement data corresponding to the first plurality of selected measurement sites are input to the second classifier 12 and the third classifier 13, respectively, to further select a second plurality of measurement sites. The measurement data corresponding to the second plurality of measurement sites selected by the second classifier 12 and the third classifier 13 are input to the first classifier 11, the second classifier 12 and the third classifier 13 respectively, to select a plurality of target sensors. The plurality of target sensors are combined to form a plurality of target sensor groups. The measurement data corresponding to the plurality of target sensor groups are input to the first classifier 11, the second classifier 12 and the third classifier 13 respectively to obtain a score of each of the target sensor groups, and the target sensor group with the highest score is defined as the abnormal sensor. Therefore, the abnormal sensor in wafer preparation is determined.

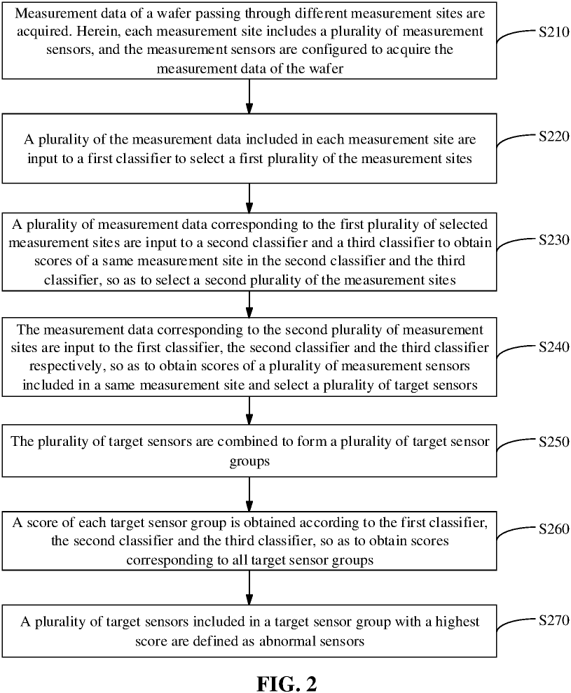

Referring to FIG. 2, a method for monitoring abnormal sensors during fabrication of a semiconductor structure is provided in a first embodiment of the disclosure, which includes the following operations.

At S210, measurement data of a wafer passing through different measurement sites are acquired. Herein, each measurement site includes a plurality of measurement sensors, and the measurement sensors are configured to acquire the measurement data of the wafer.

The wafer may include a wafer that already has abnormalities. The measurement data includes, for example, the height, the width, etc. of the wafer, and the current generated after the wafer is applied with a voltage.

The wafer needs to pass through different measurement sites during preparation, and each measurement site covers at least one machine. The machine is provided with a plurality of measurement sensors, and each measurement sensor generates measurement data after detecting the wafer.

Optionally, after the measurement data of the wafer passing through different measurement sites are acquired, abnormal data and a data missing item in the measurement data of all measurement sites need to be removed. The abnormal data include measurement data with values beyond a preset value range, and the data missing item includes a data item having no measurement data. For example, if the value range of a certain measurement value of a certain measurement site shall be 2 to 10, but this measurement value is 300, the measurement value is abnormal data and needs to be removed. The data missing item means that a certain data item shall have measurement data, for example, the current data item shall have current measurement data, but the current data item in the acquired measurement data has no measurement data, so the current data item is removed.

S220, a plurality of measurement data included in each measurement site are input to a first classifier to select a first plurality of measurement sites.

The first classifier 11 includes, for example, an Xgboost classifier.

The plurality of measurement data included in each measurement site are input to the first classifier 11 to obtain a score corresponding to each of the measurement sites. That is, a plurality of measurement data included in each measurement site are input to the first classifier 11 as a data set, and the first classifier 11 outputs the score of each of the measurement sites. Optionally, among the measurement sites that the wafer passes through, a plurality of measurement sites each with a scores greater than a preset score may be selected as the preliminarily selected measurement sites, or a plurality of measurement sites with first one or more scores in a descending order of scores may also be selected from the plurality of measurement sites as the preliminarily selected measurement sites.

Optionally, before the plurality of measurement data included in each measurement site are input to the first classifier 11, it is necessary to perform dimension reduction processing on the plurality of measurement data included in each measurement site. The dimension reduction processing is dimension reduction Principal Component Analysis (PCA) processing.

At S230, a plurality of measurement data corresponding to the first plurality of selected measurement sites are input to a second classifier and a third classifier to obtain scores of a same measurement site in the second classifier and the third classifier, so as to select a second plurality of measurement sites.

Step S230 is a further selection of the measurement sites selected in step S220. For example, at step S220, 25 measurement sites are selected from all measurement sites the wafer passes through, and at step S230, for example, 10 measurement sites are further selected from the 25 measurement sites.

The second classifier 12 includes, for example, an ANN classifier. The third classifier 13 includes, for example, an RF classifier.

After the first plurality of measurement sites is selected preliminarily at step S220, a plurality of measurement data corresponding to the first plurality of selected measurement sites are input to the second classifier 12 and the third classifier 13 to obtain the scores of the same measurement site in the second classifier 12 and the third classifier 13. That is, a plurality of measurement data corresponding to the first plurality of selected measurement sites are input to the second classifier 12 as data sets to obtain first scores, and the plurality of measurement data corresponding to the first plurality of selected measurement sites are input to the third classifier 13 to obtain second scores.

During the selection of the measurement sites, the measurement sites may be selected based on the first scores and the second scores. For example, an average value of the scores of a same measurement site in the second classifier 12 and the third classifier 13 is calculated to obtain an average score (that is, a sum average value of a first score and a second score). The average score is defined as a final evaluation score corresponding to the same measurement site. The second plurality of measurement sites with the first one or more scores of the descending order of evaluation scores are selected from the first plurality of measurement sites as the finally selected measurement sites.

Optionally, after the final evaluation score corresponding to the same measurement site is calculated, the second plurality of measurement sites with the final evaluation scores greater than a preset evaluation score may be selected from the first plurality of measurement sites as the finally selected measurement sites.

At S240, the measurement data corresponding to the second plurality of measurement sites are input to the first classifier, the second classifier and the third classifier respectively, to obtain scores of a plurality of measurement sensors included in a same measurement site, so as to select a plurality of target sensors.

The measurement data corresponding to the second plurality of measurement sites selected in step S230 serve as data sets to be respectively input to the first classifier 11, the second classifier 12 and the third classifier 13. Each of the first classifier 11, the second classifier 12 and the third classifier 13 may output a score. During determining the scores of the measurement sensors, the scores of each of a plurality of measurement sensors included in the same measurement site in the first classifier 11, the second classifier 12 and the third classifier 13 are obtained, and then a weighted sum of the scores of each of the plurality of measurement sensors included in the same measurement site in the first classifier 11, the second classifier 12 and the third classifier 13 is calculated to obtain a score corresponding to each of the plurality of measurement sensors included in the same measurement site. After the score of each measurement sensor is determined, the plurality of measurement sensors with the first one or more scores of the descending order of scores may be determined from the second plurality of measurement sites as the plurality of target sensors. Optionally, the plurality of measurement sensors with the scores exceeding a preset score may be determined from the second plurality of measurement sites as the plurality of target sensors.

When a weighted sum of the scores of each of a plurality of measurement sensors included in the same measurement site in the first classifier 11, the second classifier 12 and the third classifier 13 are calculated, it is necessary to acquire the weights for the scores of the measurement sensor in the first classifier 11, the second classifier 12 and the third classifier 13, respectively.

The weight for the score of the measurement sensor in the first classifier 11 is equal to a numerical value obtained by dividing the score of the measurement sensor in the first classifier 11 by the sum of the scores of the measurement sensor in the first classifier 11, the second classifier 12 and the third classifier 13. Similarly, the weight for the score of the measurement sensor on the second classifier 12 is equal to a numerical value obtained by dividing the score of the measurement sensor on the second classifier 12 by the sum of the scores of the measurement sensor in the first classifier 11, the second classifier 12 and the third classifier 13. The weight for the score of the measurement sensor on the third classifier 13 is equal to a numerical value obtained by dividing the score of the measurement sensor on the third classifier 13 by the sum of the scores of the measurement sensor in the first classifier 11, the second classifier 12 and the third classifier 13. For example, if the measurement sensor scores 0.9 in the first classifier 11, 0.5 on the second classifier 12 and 0.6 on the third classifier 13, the weight for the score of the measurement sensor in the first classifier 11 is 0.9/(0.9+0.5+0.6), the weight for the score of the measurement sensor on the second classifier 12 is 0.5/(0.9+0.5+0.6), the weight for the score of the measurement sensor on the third classifier 13 is 0.6/(0.9+0.5+0.6), and the score of the measurement sensor is [0.9/(0.9+0.5+0.6)] * 0.9+[0.5/(0.9+0.5+0.6)] * 0.5+[(0.6/(0.9+0.5+0.6)]*0.6, which is equal to 0.71.

The scores of the same measurement sensor in the first classifier 11, the second classifier 12 and the third classifier 13 will be different. The purpose of introducing weight to calculate the scores of the measurement sensors is to improve the score of the classifier with a high score, so that the finally calculated score of the measurement sensor is more practical.

Optionally, after a plurality of target sensors are selected, the target sensors may be regarded as abnormal sensors.

At S250, the plurality of target sensors are combined to form a plurality of target sensor groups.

What affects wafer abnormality is not only the measurement sensors that are abnormal themselves, but also a combination of the measurement sensors may be the cause of wafer abnormality. Therefore, in the embodiment, the plurality of target sensors are also combined to form a plurality of target sensor groups. During combination, the plurality of target sensors may be randomly combined to form a plurality of target sensor groups. For example, target sensor 1, target sensor 2, target sensor 3, target sensor 4, target sensor 5 and target sensor 6 are all combined in pairs. The plurality of obtained target sensor groups may be (target sensor 1 and target sensor 2), (target sensor 2 and target sensor 3), (target sensor 3 and target sensor 4), (target sensor 4 and target sensor 5), (target sensor 1 and target sensor 3), (target sensor 1 and target sensor 4), (target sensor 1 and target sensor 5), (target sensor 2 and target sensor 4), (target sensor 2 and target sensor 5), (target sensor 3 and target sensor 5), etc. Or, random combination is performed. The plurality of obtained target sensor groups may be (target sensor 1, target sensor 2, target sensor 3), (target sensor 1, target sensor 3, target sensor 4), (target sensor 1, target sensor 3, target sensor 5), (target sensor 2, target sensor 3, target sensor 4), etc. The random combination mode may be selected on actual demands, which is not limited in the disclosure.

At S260, the score of each target sensor group is obtained according to the first classifier, the second classifier and the third classifier, so as to obtain the scores corresponding to all target sensor groups.

The measurement data corresponding to the plurality of target sensor groups are input to the first classifier 11, the second classifier 12 and the third classifier 13 respectively, so as to obtain the scores of a same target sensor group in the first classifier 11, the second classifier 12 and the third classifier 13, respectively. Then, a weighted sum of the scores of a same target sensor group in the first classifier 11, the second classifier 12 and the third classifier 13 respectively is calculated to obtain the score corresponding to the same target sensor group, so as to obtain the scores corresponding to all target sensor groups.

That is, the measurement data corresponding to each of the target sensor groups serve as data sets to be respectively input to the first classifier 11, the second classifier 12 and the third classifier 13, to obtain the scores output by the first classifier 11, the second classifier 12 and the third classifier 13, respectively. Then, the weight of the score of the target sensor group in a target classifier is acquired, and the target classifier is any one of the first classifier 11, the second classifier 12 and the third classifier 13. The weight of the score of the target sensor group in the target classifier is equal to a numerical value obtained by dividing the score of the target sensor group in the target classifier by the sum of the scores of the target sensor group in the first classifier 11, the second classifier 12 and the third classifier 13. The score corresponding to the same target sensor group is obtained according to the weight, so as to obtain the scores corresponding to all target sensor groups.

As described in S240, for example, if the target sensor group scores 0.7 in the first classifier 11, 0.3 on the second classifier 12 and 0.5 on the third classifier 13, the weight of the score of the target sensor group in the first classifier 11 is 0.7/(0.7+0.3+0.5), the weight of the score of the target sensor group on the second classifier 12 is 0.3/(0.7+0.3+0.5), the weight of the score of the target sensor group on the third classifier 13 is 0.5/(0.7+0.3+0.5), and the score of the target sensor group is [0.7/(0.7+0.3+0.5)] * 0.7+[0.3/(0.7+0.3+0.5)] * 0.3+[(0.5/(0.7+0.3+0.5)]*0.5, which is equal to 0.554.

At S270, a plurality of target sensors included in the target sensor group with the highest score are defined as abnormal sensors.

The target sensor group with the highest score may be one of the target sensor groups, or it may be a plurality of target sensor groups with the first one or more scores in the descending order of scores.

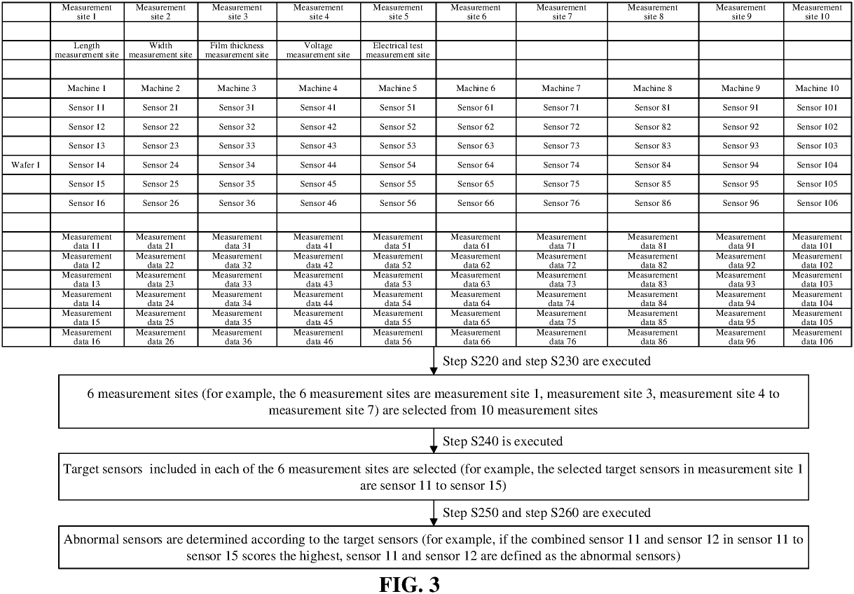

In order to better understand how the method for monitoring abnormal sensors during fabrication of a semiconductor structure provided in this embodiment is implemented, an example is shown in FIG. 3. In FIG. 3, step S210 is performed first, so as to acquire the measurement data (measurement data 11 to 16, measurement data 21 to 26, measurement data 31 to 36, measurement data 41 to 46, measurement data 51 to 56, measurement data 61 to 66, measurement data 71 to 76, measurement data 81 to 86, measurement data 91 to 96, and measurement data 101 to 106) of all sensors (sensors 11 to 16, sensors 21 to 26, sensors 31 to 36, sensors 41 to 46, sensors 51 to 56, sensors 61 to 66, sensors 71 to 76, sensors 81 to 86, sensors 91 to 96, sensors 101 to 106) of wafer 1 in measurement sites 1 to 10. Then, steps S220 and S230 are executed, then six measurement sites are selected from the measurement sites 1 to 10. Then, step S240 is executed to select a plurality of target sensors. Then, step S250 and step S260 are executed to determine the abnormal sensor.

According to the method for monitoring the abnormal sensors during fabrication of a semiconductor structure provided in the embodiment, the acquired measurement data of the wafer passing through different measurement sites are input to the first classifier, and a first plurality of measurement sites are preliminarily selected. Then, a plurality of measurement data corresponding to the plurality of selected measurement sites are input to the second classifier 12 and the third classifier 13, and then a second plurality of measurement sites are further selected. The measurement data corresponding to the second plurality of measurement sites selected by the second classifier 12 and the third classifier 13 are input to the first classifier 11, the second classifier 12 and the third classifier 13 respectively, to select a plurality of target sensors. The plurality of target sensors are combined to form a plurality of target sensor groups. The measurement data corresponding to the plurality of target sensor groups are respectively input to the first classifier 11, the second classifier 12 and the third classifier 13 to obtain the scores of each of the target sensor groups, and a plurality of target sensors in the target sensor group with the highest score are defined as abnormal sensors. Therefore, the abnormal sensors in wafer preparation are determined. Compared with a method for determining abnormal sensors by analyzing the measurement data one by one, the method provided in the embodiment may use the classifier to determine the abnormal sensors faster, and the analysis efficiency is faster.

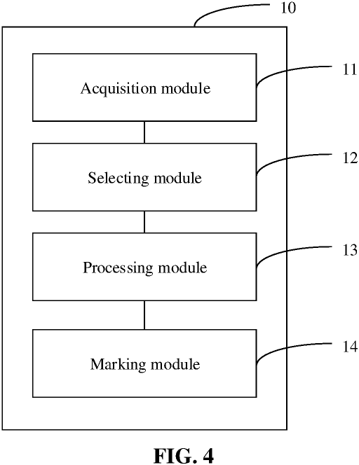

Referring to FIG. 4, an apparatus 10 for monitoring abnormal sensors during fabrication of a semiconductor structure is provided in embodiment II of the disclosure, which includes an acquisition module 11, a selecting module 12, a processing module 13, and a marking module 14.

The acquisition module 11 is configured to acquire measurement data of a wafer passing through different measurement sites. Herein, each measurement site includes a plurality of measurement sensors, and the measurement sensors are configured to acquire the measurement data of the wafer.

The selecting module 12 is configured to input a plurality of measurement data included in each measurement site to a first classifier to select a first plurality of measurement sites.

The selecting module 12 is further configured to input a plurality of measurement data corresponding to the first plurality of selected measurement sites to a second classifier and a third classifier to obtain scores of a same measurement site in the second classifier and the third classifier, so as to select a second plurality of measurement sites.

The selecting module 12 is further configured to input the measurement data corresponding to the second plurality of measurement sites to the first classifier, the second classifier and the third classifier respectively, to obtain scores of a plurality of measurement sensors included in a same measurement site, so as to select a plurality of target sensors.

The processing module 13 is configured to combine the plurality of target sensors to form a plurality of target sensor groups.

The processing module 13 is further configured to obtain, according to the first classifier, the second classifier and the third classifier, a score of each target sensor group, so as to obtain scores corresponding to all target sensor groups.

The marking module 14 is configured to define a plurality of target sensors in a target sensor group with the highest score as abnormal sensors.

The selecting module 12 is specifically configured to input the plurality of the measurement data included in each measurement site to the first classifier to obtain a score corresponding to the measurement site, and select a first plurality of measurement sites with first one or more scores in a descending order of scores from a plurality of measurement sites.

The selecting module 12 is specifically configured to input the plurality of measurement data corresponding to the first plurality of selected measurement sites to a second classifier and a third classifier to obtain the scores of the same measurement site in the second classifier and the third classifier; calculate an average value of the scores of the same measurement site in the second classifier and the third classifier to obtain an average score, and define the average score as a final corresponding to the same measurement site; and select the second plurality of measurement sites with the first one or more scores in a descending order of evaluation scores from the first plurality of measurement sites.

The selecting module 12 is specifically configured to input the measurement data corresponding to the second plurality of measurement sites to the first classifier, the second classifier and the third classifier respectively, so as to obtain the scores of the plurality of measurement sensors included in the same measurement site in the first classifier, the second classifier and the third classifier, respectively; calculating a weighted sum of the scores of the plurality of measurement sensors included in the same measurement site in the first classifier, the second classifier and the third classifier respectively to obtain scores corresponding to the plurality of measurement sensors included in the same measurement site; and determine a plurality of measurement sensors with the first one or more scores in a descending order of scores from the second plurality of measurement sites as the plurality of target sensors.

The processing module 13 is specifically configured to input measurement data corresponding to the plurality of target sensor groups to the first classifier, the second classifier and the third classifier respectively, so as to obtain scores of a same target sensor group in the first classifier, the second classifier and the third classifier respectively; and calculate a weighted sum of the scores of the same target sensor group in the first classifier, the second classifier and the third classifier respectively to obtain the score corresponding to the same target sensor group, so as to obtain the scores corresponding to all target sensor groups.

The processing module 13 is specifically configured to: acquire a weight of the score of the target sensor group in a target classifier, the weight is equal to a numerical value obtained by dividing the score of the target sensor group in the target classifier by a sum of the scores of the target sensor group in the first classifier, the second classifier and the third classifier, and the target classifier is any of the first classifier, the second classifier or the third classifier; and obtain, according to the weight, the score corresponding to the same target sensor group, so as to obtain the scores corresponding to all target sensor groups.

The processing module 13 is further configured to perform dimension reduction processing on the plurality of measurement data included in each measurement site.

The first classifier includes an Xgboost classifier. The second classifier includes an ANN classifier. The third classifier includes an RF classifier.

The processing module 13 is further configured to remove abnormal data and a data missing item from the measurement data of all measurement sites. The abnormal data includes measurement data with values beyond a preset value range, and the data missing item includes a data item having no measurement data.

The implementation method of the apparatus 10 for monitoring abnormal sensors during fabrication of a semiconductor structure is consistent with the method for monitoring the abnormal sensors during fabrication of a semiconductor structure as described in any of the above embodiments, which will not be repeated here.

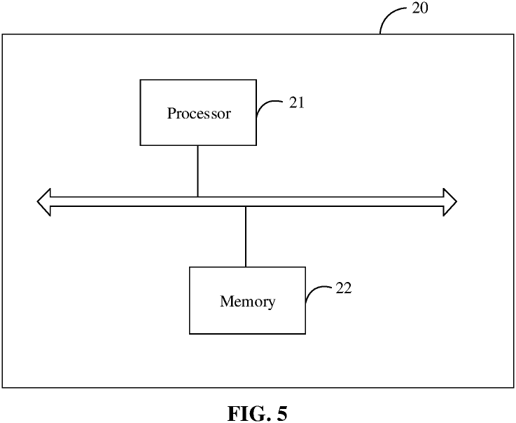

Referring to FIG. 5, an electronic device 20 is further provided in embodiment III of the disclosure, which includes: a processor 21 and a memory 22 in communication connection with the processor 21. The memory 22 stores a computer execution instruction. The processor 21 executes the computer execution instruction stored in the memory 22 to implement the method for monitoring abnormal sensors during fabrication of a semiconductor structure as described in any of the above embodiments.

The disclosure further provides a computer readable storage medium, and a computer execution instruction is stored in the computer readable storage medium. When the computer execution instruction is executed by a processor, the method for monitoring abnormal sensors during fabrication of a semiconductor structure provided in any of the embodiments above is implemented.

The disclosure further provides a computer program product, which includes a computer program. The method for monitoring abnormal sensors during fabrication of a semiconductor structure provided in any of the embodiments above is implemented when the computer program is executed by a processor.

According to the method for monitoring the abnormal sensors during fabrication of a semiconductor structure provided in the disclosure, the acquired measurement data of the wafer passing through different measurement sites are input to the first classifier, and a first plurality of measurement sites are preliminarily selected. Then, a plurality of measurement data corresponding to the plurality of selected measurement sites are input to the second classifier and the third classifier, and then a second plurality of measurement sites are selected. The measurement data corresponding to the second plurality of measurement sites selected by the second classifier and the third classifier are input to the first classifier, the second classifier and the third classifier respectively, to select a plurality of target sensors. The plurality of target sensors are combined to form a plurality of target sensor groups. The measurement data corresponding to the plurality of target sensor groups are respectively input to the first classifier, the second classifier and the third classifier to obtain the score of each of the target sensor groups, and a plurality of target sensors in the target sensor group with the highest score are defined as abnormal sensors. Therefore, the abnormal sensors in wafer fabrication are determined. Compared with a method for determining abnormal sensors by analyzing the measurement data one by one, the method provided in the disclosure may use the classifier to determine the abnormal sensors faster, and the analysis efficiency is faster.

It is to be noted that, the computer readable storage medium may be a Read Only Memory (ROM), a Programmable Read-Only Memory (PROM), an Erasable Programmable Read-Only Memory (EPROM), an Electrically Erasable Programmable Read-Only Memory (EEPROM), a Ferromagnetic Random Access Memory (FRAM), a Flash Memory, a magnetic surface memory, a compact disc, a Compact Disc Read-Only Memory (CD-ROM) and the like. The computer readable storage medium may also be various electronic devices including one or any combination of the above memories, such as mobile phones, computers, tablet devices and personal digital assistants.

It is to be noted that, in this context, the terms “include”, “containing” or any other variation thereof are intended to cover non-exclusive inclusion, so that a process, method, article or device that includes a series of elements includes not only those elements, but also other elements not explicitly listed, or elements inherent in such process, method, article or device. Without further restrictions, the element defined by the statement “including a...” does not exclude the existence of another same element in the process, method, article or device including the element.

The serial numbers of the embodiments of the application are merely for description and do not represent a preference of the embodiments.

Through the description of the above embodiments, those skilled in the art can clearly understand that the above embodiment method can be realized by means of software and necessary general hardware platforms. Of course, it can also be realized by hardware, but in many cases, the former is a better embodiment. Based on this understanding, the technical solution of the disclosure essentially or the part that contributes to the traditional art can be embodied in the form of a software product. The computer software product is stored in a storage medium (such as a ROM/RAM, a magnetic disc and a compact disc), including several instructions to make a terminal device (which may be a mobile phone, a computer, a server, an air conditioner, or a network device, etc.) to execute the method described in various embodiments of the disclosure.

The disclosure is described with reference to the flowcharts and/or block diagrams of the method, the device (system), and the computer program product according to the embodiment of the disclosure. It should be understood that, each process and/or block in the flowchart and/or block diagram and the combination of processes and/or blocks in the flowchart and/or block diagram may be implemented by a computer program instruction. These computer program instructions may be provided for the processor of a general-purpose computer, a special-purpose computer, an embedded processor or other programmable data processing devices to generate a machine, and therefore, a device for realizing the functions specified in one or more processes of the flowchart and/or one or more blocks of the block diagram is generated through the instruction executed by a processor of a computer or other programmable data processing devices.

These computer program instructions may also be stored in the computer-readable memory which can guide the computer or other programmable data processing devices to work in a particular way, so that the instructions stored in the computer-readable memory generate a product including an instruction device. The instruction device implements the specified functions in one or more flows of the flowchart and/or one or more blocks of the block diagram.

These computer program instructions may also be loaded on the computer or other programmable data processing devices, so that a series of operation steps are performed on the computer or other programmable data processing devices to generate the processing implemented by the computer, and the instructions executed on the computer or other programmable data processing devices provide the steps for implementing the specified functions in one or more flows of the flowchart and/or one or more blocks of the block diagram.

The above is only the preferred embodiment of the disclosure and does not limit the scope of the patent of the disclosure. Any equivalent structure or equivalent process transformation made by using the contents of the description and drawings of the application, or directly or indirectly applied in other relevant technical fields, are similarly included in the scope of patent protection of the disclosure.

1. A method for monitoring abnormal sensors during fabrication of a semiconductor structure, comprising:
acquiring measurement data of a wafer passing through different measurement sites, wherein each measurement site comprises a plurality of measurement sensors, and the measurement sensors are configured to acquire the measurement data of the wafer;
inputting a plurality of measurement data included in each measurement site to a first classifier to select a first plurality of measurement sites;
inputting a plurality of measurement data corresponding to the first plurality of selected measurement sites to a second classifier and a third classifier to obtain scores of a same measurement site in the second classifier and the third classifier, so as to select a second plurality of measurement sites;
inputting measurement data corresponding to the second plurality of measurement sites to the first classifier, the second classifier and the third classifier respectively, to obtain scores of a plurality of measurement sensors included in a same measurement site, so as to select a plurality of target sensors;
combining the plurality of target sensors to form a plurality of target sensor groups;
obtaining, according to the first classifier, the second classifier and the third classifier, a score of each target sensor group, so as to obtain scores corresponding to all target sensor groups; and
defining a plurality of target sensors included in a target sensor group with a highest score as abnormal sensors.

2. The method of claim 1, wherein inputting the plurality of the measurement data included in each measurement site to the first classifier to select the first plurality of measurement sites comprises:
inputting the plurality of the measurement data included in each measurement site to the first classifier to obtain a score corresponding to the measurement site; and
selecting the first plurality of measurement sites with first one or more scores in a descending order of scores from a plurality of measurement sites.

3. The method of claim 2, wherein inputting the plurality of measurement data corresponding to the first plurality of selected measurement sites to the second classifier and the third classifier to obtain the scores of the same measurement site in the second classifier and the third classifier, so as to select the second plurality of measurement sites comprises:
inputting the plurality of measurement data corresponding to the first plurality of selected measurement sites to the second classifier and the third classifier to obtain the scores of the same measurement site in the second classifier and the third classifier;
calculating an average value of the scores of the same measurement site in the second classifier and the third classifier to obtain an average score, and defining the average score as a final evaluation score corresponding to the same measurement site; and
selecting the second plurality of measurement sites with first one or more scores in a descending order of evaluation scores from the first plurality of measurement sites.

4. The method of claim 1, wherein inputting the measurement data corresponding to the second plurality of measurement sites to the first classifier, the second classifier and the third classifier respectively, to obtain the scores of the plurality of measurement sensors included in the same measurement site, so as to select the plurality of target sensors comprises:
inputting the measurement data corresponding to the second plurality of measurement sites to the first classifier, the second classifier and the third classifier respectively, so as to obtain the scores of the plurality of measurement sensors included in the same measurement site in the first classifier, the second classifier and the third classifier, respectively;
calculating a weighted sum of the scores of the plurality of measurement sensors included in the same measurement site in the first classifier, the second classifier and the third classifier respectively to obtain scores corresponding to the plurality of measurement sensors included in the same measurement site; and
determining a plurality of measurement sensors with first one or more scores in a descending order of scores from the second plurality of measurement sites as the plurality of target sensors.

5. The method of claim 1, wherein obtaining, according to the first classifier, the second classifier and the third classifier, the score of each target sensor group, so as to obtain the scores corresponding to all target sensor groups comprises:
inputting measurement data corresponding to the plurality of target sensor groups to the first classifier, the second classifier and the third classifier respectively, so as to obtain scores of a same target sensor group in the first classifier, the second classifier and the third classifier, respectively; and
calculating a weighted sum of the scores of the same target sensor group in the first classifier, the second classifier and the third classifier respectively to obtain the score corresponding to the same target sensor group, so as to obtain the scores corresponding to all target sensor groups.

6. The method of claim 5, wherein calculating the weighted sum of the scores of the same target sensor group in the first classifier, the second classifier and the third classifier respectively to obtain the score corresponding to the same target sensor group, so as to obtain the scores corresponding to all target sensor groups comprises:
acquiring a weight of a score of the target sensor group in a target classifier, the weight being equal to a numerical value obtained by dividing the score of the target sensor group in the target classifier by a sum of the scores of the target sensor group in the first classifier, the second classifier and the third classifier, and the target classifier being any of the first classifier, the second classifier or the third classifier; and
obtaining, according to the weight, the score corresponding to the same target sensor group so as to obtain the scores corresponding to all target sensor groups.

7. The method of claim 1, before inputting the plurality of measurement data included in each measurement site to the first classifier, further comprising:
performing dimension reduction processing on the plurality of measurement data included in each measurement site.

8. The method of claim 1, wherein the first classifier comprises an Xgboost classifier, the second classifier comprising an Artificial Neural Network (ANN) classifier, and the third classifier comprising a Random Forest (RF) classifier.

9. The method of claim 1, further comprising: after acquiring the measurement data of the wafer passing through different measurement sites,
removing abnormal data and a data missing item from measurement data of all measurement sites, the abnormal data comprising measurement data with values beyond a preset value range, and the data missing item comprising a data item having no measurement data.

10. An electronic device, comprising:
a processor; and
a memory in communication connection with the processor,
wherein the memory is configured to store a computer execution instruction, and
wherein the processor is configured to execute the computer execution instruction stored in the memory to implement the following operations:
acquiring measurement data of a wafer passing through different measurement sites, wherein each measurement site comprises a plurality of measurement sensors, and the measurement sensors are configured to acquire the measurement data of the wafer;
inputting a plurality of measurement data included in each measurement site to a first classifier to select a first plurality of measurement sites;
inputting a plurality of measurement data corresponding to the first plurality of selected measurement sites to a second classifier and a third classifier to obtain scores of a same measurement site in the second classifier and the third classifier, so as to select a second plurality of measurement sites;
inputting measurement data corresponding to the second plurality of measurement sites to the first classifier, the second classifier and the third classifier respectively, to obtain scores of a plurality of measurement sensors included in a same measurement site, so as to select a plurality of target sensors;
combining the plurality of target sensors to form a plurality of target sensor groups;
obtaining, according to the first classifier, the second classifier and the third classifier, a score of each target sensor group, so as to obtain scores corresponding to all target sensor groups; and
defining a plurality of target sensors included in a target sensor group with a highest score as abnormal sensors.

11. The electronic device of claim 10, wherein the processor is configured to execute the computer execution instruction stored in the memory to input the plurality of the measurement data included in each measurement site to the first classifier to obtain a score corresponding to the measurement site; and select the first plurality of measurement sites with first one or more scores in a descending order of scores from a plurality of measurement sites.

12. The electronic device of claim 11, wherein the processor is configured to execute the computer execution instruction stored in the memory to:
input the plurality of measurement data corresponding to the first plurality of selected measurement sites to the second classifier and the third classifier to obtain the scores of the same measurement site in the second classifier and the third classifier;
calculate an average value of the scores of the same measurement site in the second classifier and the third classifier to obtain an average score, and define the average score as a final evaluation score corresponding to the same measurement site; and
select the second plurality of measurement sites with first one or more scores in a descending order of evaluation scores from the first plurality of measurement sites.

13. The electronic device of claim 10, wherein the processor is configured to execute the computer execution instruction stored in the memory to:
input the measurement data corresponding to the second plurality of measurement sites to the first classifier, the second classifier and the third classifier respectively, so as to obtain the scores of the plurality of measurement sensors included in the same measurement site in the first classifier, the second classifier and the third classifier, respectively;
calculate a weighted sum of the scores of the plurality of measurement sensors included in the same measurement site in the first classifier, the second classifier and the third classifier respectively to obtain scores corresponding to the plurality of measurement sensors included in the same measurement site; and
determine a plurality of measurement sensors with first one or more scores in a descending order of scores from the second plurality of measurement sites as the plurality of target sensors.

14. The electronic device of claim 10, wherein the processor is configured to execute the computer execution instruction stored in the memory to:
input measurement data corresponding to the plurality of target sensor groups to the first classifier, the second classifier and the third classifier respectively, so as to obtain scores of a same target sensor group in the first classifier, the second classifier and the third classifier, respectively; and
calculate a weighted sum of the scores of the same target sensor group in the first classifier, the second classifier and the third classifier respectively to obtain the score corresponding to the same target sensor, so as to obtain the scores corresponding to all target sensor groups.

15. The electronic device of claim 14, wherein the processor is configured to execute the computer execution instruction stored in the memory to:
acquire a weight of a score of the target sensor group in a target classifier, the weight is equal to a numerical value obtained by dividing the score of the target sensor group in the target classifier by a sum of the scores of the target sensor group in the first classifier, the second classifier and the third classifier, and the target classifier is any of the first classifier, the second classifier or the third classifier; and
obtain, according to the weight, the score corresponding to the same target sensor group so as to obtain the scores corresponding to all target sensor groups.

16. The electronic device of claim 10, wherein the processor is configured to execute the computer execution instruction stored in the memory to perform dimension reduction processing on the plurality of measurement data included in each measurement site.

17. The electronic device of claim 10, wherein the first classifier comprises an Xgboost classifier, the second classifier comprising an Artificial Neural Network (ANN) classifier, and the third classifier comprising a Random Forest (RF) classifier.

18. The electronic device of claim 10, wherein the processor is configured to execute the computer execution instruction stored in the memory to remove abnormal data and a data missing item from measurement data of all measurement sites, the abnormal data comprises measurement data with values beyond a preset value range, and the data missing item comprises a data item having no measurement data.

19. A non-transitory computer-readable storage medium, wherein the non-transitory computer-readable storage medium stores a computer execution instruction, which, when executed, enables a computer to execute the following operations:
acquiring measurement data of a wafer passing through different measurement sites, wherein each measurement site comprises a plurality of measurement sensors, and the measurement sensors are configured to acquire the measurement data of the wafer;
inputting a plurality of measurement data included in each measurement site to a first classifier to select a first plurality of measurement sites;
inputting a plurality of measurement data corresponding to the first plurality of selected measurement sites to a second classifier and a third classifier to obtain scores of a same measurement site in the second classifier and the third classifier, so as to select a second plurality of measurement sites;
inputting measurement data corresponding to the second plurality of measurement sites to the first classifier, the second classifier and the third classifier respectively, to obtain scores of a plurality of measurement sensors included in a same measurement site, so as to select a plurality of target sensors;
combining the plurality of target sensors to form a plurality of target sensor groups;
obtaining, according to the first classifier, the second classifier and the third classifier, a score of each target sensor group, so as to obtain scores corresponding to all target sensor groups; and
defining a plurality of target sensors included in a target sensor group with a highest score as abnormal sensors.
